(19) United States
(12) Patent Application Publication
(10) Pub. No.: US 2014/0154627 A1
(43) Pub. Date: Jun. 5, 2014

(54) NEGATIVE TYPE PHOTOSENSITIVE RESIN COMPOSITION, RESIN FILM, AND ELECTRONIC DEVICE

(71) Applicant: Akihiro Tanabe, Tokyo (JP)

(72) Inventor: Akihiro Tanabe, Tokyo (JP)

(73) Assignee: ZEON CORPORATION, Tokyo (JP)

(21) Appl. No.: 14/233,238

(22) PCT Filed: Jul. 19, 2012
(86) PCT No.: PCT/JP2012/068330

§ 371 Date: Jan. 16, 2014

(30) Foreign Application Priority Data
Jul. 20, 2011 (JP) 2011-158748

(51) Int. Cl. G03F 7/075

(52) U.S. Cl. CPC G03F 7/0757
USPC 430/280.1

(57) ABSTRACT

A negative type photosensitive resin composition containing a resin compound (A) which has a weight average molecular weight of 1000 or more, a (meth)acryloyl compound (B), a silane-modified resin (C), a radical-generating type photopolymerization initiator (D), and a silicon atom-free epoxy group-containing cross-linking agent (E), wherein the resin compound (A) contains a resin compound (A1) which has two or more (meth)acryloyl groups in a molecule and which has a carboxyl group which reacts with the epoxy group and the (meth)acryloyl compound (B) has a weight average molecular weight of less than 1000 and has two or more (meth)acryloyl groups in a molecule, is provided.

### TECHNICAL FIELD

The present invention relates to a negative type photosensitive resin composition and to a resin film and electronic device which are obtained by using this negative type photosensitive resin composition, more specifically relates to a negative type photosensitive resin composition which is excellent in solubility in a diluent solvent and which can give a resin film which is excellent in pattern-forming ability by development and to a resin film and electronic device which are obtained by using this negative type photosensitive resin composition.

### BACKGROUND ART

Organic EL devices and liquid crystal display devices and other various types of display devices, integrated circuit devices, solid state imaging devices, color filters, black matrices, and other electronic devices are provided with various resin films as protective films for preventing deterioration or damage, flattening films for flattening the device surfaces and interconnects, electrical insulating films for maintaining an electrical insulating property etc. Further, organic EL devices are provided with picture element separating films constituted by resin films for separating the light emitting parts. Furthermore, display devices or integrated circuit devices for thin film transistor type liquid crystal use etc. are provided with interlayer insulating films constituted by resin films for insulating the distances between interconnects which are arranged in layers.

In the past, as resin materials for forming these resin films, epoxy resins and other thermocurable resin materials have generally been used. In recent years, along with the higher densities of interconnects and devices, for these resin materials as well, development of new resin materials which are low in dielectric permittivity and excellent in other electrical characteristics is being sought.

To meet with these demands, for example, Patent Document 1 discloses a photosensitive resin composition which includes a photopolymerizable acrylate oligomer, a bifunctional or higher polyfunctional photopolymerizable acrylate monomer, a photopolymerizable compound which has ethylenically unsaturated double bonds and carboxyl groups, an aminosilane-modified epoxy resin, a photopolymerization initiator, and an organic solvent. However, in the photosensitive resin composition which is described in Patent Document 1, the pattern-forming ability by development, in particular the adhesion after development (adhesion of developed patterns in case of making the width of the developed patterns finer and increasing the definition) is not necessarily sufficient. For this reason, improvement in the pattern-forming ability by development has been sought.

### PRIOR ART DOCUMENTS

### Patent Documents

Patent Document 1: Japanese Patent Publication No. 5-295080A

### SUMMARY OF THE INVENTION

### Problem to be Solved by the Invention

The present invention has as its object the provision of a negative type photosensitive resin composition which is excellent in solubility in a diluent solvent and which can give a resin film which is excellent in pattern-forming ability by development. Further, the present invention has as its object the provision of a resin film which is obtained by using such a negative type photosensitive resin composition and of an electronic device which is provided with that resin film.

### Means for Solving the Problems

The inventors engaged in in-depth research so as to achieve the above object and as a result discovered that the above object can be achieved by a resin composition which contains a resin compound which has a weight average molecular weight of 1000 or more and which has two or more (meth)acryloyl groups in a molecule, a (meth)acryloyl compound which has a weight average molecular weight of less than 1000 and which has two or more (meth)acryloyl groups in a molecule, a silane-modified resin, a radical-generating type photopolymerization initiator, and an epoxy group-containing cross-linking agent which does not contain a silicon atom and which has, as that resin compound, one which has a carboxyl group which reacts with an epoxy group, and thereby completed the present invention.

That is, according to the present invention, there is provided a negative type photosensitive resin composition which contains a resin compound (A) which has a weight average molecular weight of 1000 or more, a (meth)acryloyl compound (B), a silane-modified resin (C), a radical-generating type photopolymerization initiator (D), and a silicon atom-free epoxy group-containing cross-linking agent (E), wherein the resin compound (A) contains a resin compound (A1) which has two or more (meth)acryloyl groups in a molecule and which has a carboxyl group which reacts with that epoxy group and the (meth)acryloyl compound (B) has a weight average molecular weight of less than 1000 and has two or more (meth)acryloyl groups in a molecule.

Preferably, the resin compound (A) further contains a resin compound (A2) which has two or more (meth)acryloyl groups in a molecule and does not have a carboxyl group.

Preferably, the resin compound (A) further contains a resin compound (A3) which has two or more (meth)acryloyl groups in a molecule and has a urethane structure.

Preferably, the epoxy group-containing cross-linking agent (E) has a molecular weight of 200 to 550, and a content of the epoxy group-containing cross-linking agent (E) is 30 to 150 parts by weight with respect to 100 parts by weight of the resin compound (A).

Preferably, the epoxy group-containing cross-linking agent (E) is a glycidyl ether compound.

Further, according to the present invention, there is provided a resin film which is obtained by using any of the above negative type photosensitive resin compositions.

Furthermore, according to the present invention, there is provided an electronic device which is provided with the above resin film.

### Effects of the Invention

According to the present invention, it is possible to provide a resin composition which is excellent in solubility in a diluent solvent and which can give a resin film which is excellent in pattern-forming ability by development and an electronic device which is provided with a resin film comprised of such a resin composition.

### DESCRIPTION OF EMBODIMENTS

The negative type photosensitive resin composition of the present invention is a photosensitive resin composition of negative type which contains a resin compound (A) which has a weight average molecular weight of 1000 or more, a (meth)acryloyl compound (B), a silane-modified resin (C), a radical-generating type photopolymerization initiator (D), and a silicon atom-free epoxy group-containing cross-linking agent (E), where the resin compound (A) contains a resin compound (A1) which has two or more (meth)acryloyl groups in a molecule and which has a carboxyl group which reacts with the epoxy group and where the (meth)acryloyl compound (B) has a weight average molecular weight of less than 1000 and has two or more (meth)acryloyl groups in a molecule.

(Resin Compound (A))

The resin compound (A) which has a weight average molecular weight of 1000 or more (below, suitably referred to as the “resin compound (A)”) used in the present invention contains at least a resin compound (A1) which has two or more (meth)acryloyl groups in a molecule and which has a carboxyl group which reacts with the epoxy group.

The carboxyl group which reacts with the epoxy group forming part of the resin compound (A1) which has two or more (meth)acryloyl groups in a molecule and which has a carboxyl group which reacts with the epoxy group used in the present invention (below, suitably referred to as the “carboxyl group-containing resin compound (A1)”) should be a carboxyl group having an active hydrogen atom which can react with an epoxy group and may be derived from a dicarboxylic acid anhydride (one giving a carboxyl group having an active hydrogen atom which can react with an epoxy group by hydrolysis).

The carboxyl group-containing resin compound (A1) should be a resin which has a weight average molecular weight of 1000 or more, which has two or more (meth)acryloyl groups in a molecule, and which has a carboxyl group which reacts with an epoxy group. For example, a resin comprised of a homopolymer of a compound which has two or more (meth)acryloyl groups in a molecule or copolymer of this and a copolymerizable monomer which is modified by at least one compound which is selected from a carboxylic acid which has a (meth)acryloyl group and a carboxylic acid anhydride which has a (meth)acryloyl group can be used.

As the compound which has two or more (meth)acryloyl groups in a molecule, ethyleneglycol dimethacrylate, diethyleneglycol dimethacrylate, triethyleneglycol dimethacrylate, tricyclodecane dimethanol di(meth)acrylate, neopentylglycol dimethacrylate, 1,6-hexanediol di(meth)acrylate, pentaerythritol triacrylate, trimethylolpropane tri(meth)acrylate, pentaerythritol tetraacrylate, dipentaerythritol pentaacrylate, dipentaerythritol hexaacrylate, ethoxylated isocyanulate triacrylate, ethoxylated glycerin triacrylate, a bifunctional or higher cresol novolac type epoxy acrylate, and other bifunctional or higher epoxy acrylates, a bifunctional or higher phenol resin-modified epoxy acrylate, bifunctional or higher urethane acrylate, polyoxypropylene monoacrylate, etc. may be mentioned. Among these as well, from the viewpoint of being able to lighten the shrinkage stress at the time of UV curing, a bifunctional or higher urethane acrylate (urethane structure-containing resin compound (A3)) is preferable.

Further, as specific examples of the carboxylic acid which has a (meth)acryloyl group, (meth)acrylic acid [meaning acrylic acid and/or methacrylic acid, same below for methyl (meth)acrylate etc.], crotonic acid, maleic acid, fumaric acid, citraconic acid, mesaconic acid, glutaconic acid, mono-(2-((meth)acryloyloxy)ethyl)phthalate, N-(carboxyphenyl)maleimide, N-(carboxyphenyl)(meth)acrylamide, etc. may be mentioned.

As specific examples of a carboxylic acid anhydride which has a (meth)acryloyl group, maleic acid anhydride, citraconic acid anhydride, etc. may be mentioned.

Further, as the other copolymerizable monomer, an epoxy group-containing acrylate compound, oxetane group-containing acrylate compound, or other copolymerizable monomers other than an acrylate-based monomer or acrylate etc. may be mentioned.

As specific examples of the epoxy group-containing acrylate compound, glycidyl acrylate, glycidyl methacrylate, glycidyl α-ethyl acrylate, glycidyl α-n-propyl acrylate, glycidyl α-n-butyl acrylate, 3,4-epoxybutyl acrylate, 3,4-epoxybutyl methacrylate, 6,7-epoxyheptyl acrylate, 6,7-epoxyheptyl methacrylate, 6,7-epoxyheptyl α-ethyl acrylate, 3,4-epoxycyclohexylmethyl acrylate, 3,4-epoxycyclohexylmethyl methacrylate, etc. may be mentioned.

As specific examples of the oxetane group-containing acrylate compound, (3-methyloxetan-3-yl)methyl (meth)acrylate, (3-ethyloxetan-3-yl)methyl (meth)acrylate, (3-methyloxetan-3-yl)ethyl (meth)acrylate, (3-ethyloxetan-3-yl)ethyl (meth)acrylate, (3-chloromethyloxetan-3-yl)methyl (meth)acrylate, (oxetan-2-yl)methyl (meth)acrylate, (2-methyloxetan-2-yl)methyl (meth)acrylate, (2-ethyloxetan-2-yl)methyl (meth)acrylate, (1-methyl-1-oxetayl-2-phenyl)-3-(meth)acrylate, (1-methyl-1-oxetanyl)-2-trifluoramethyl-3-(meth)acrylate, (1-methyl-1-oxetayl)-4-trifluoramethyl-2-(meth)acrylate, etc. may be mentioned.

Among these, (meth)acrylic acid, maleic anhydride, glycidyl (meth)acrylate, and 6,7-epoxyheptyl methacrylate are preferable.

As other acrylate-based monomers, methyl (meth)acrylate, ethyl (meth)acrylate, propyl (meth)acrylate, isopropyl(meth)acrylate, butyl(meth)acrylate, isobutyl(meth)acrylate, t-butyl(meth)acrylate, amyl(meth)acrylate, isoamyl(meth)acrylate, hexyl(meth)acrylate, heptyl(meth)acrylate, octyl(meth)acrylate, isooctyl(meth)acrylate, ethylhexyl(meth)acrylate, nonyl(meth)acrylate, decyl(meth)acrylate, isodecyl(meth)acrylate, undecyl(meth)acrylate, dodecyl(meth)acrylate, lauryl(meth)acrylate, stearyl(meth)acrylate, isostearyl(meth)acrylate, or other alkyl(meth)acrylates; hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, or other hydroxyalkyl (meth)acrylates; phenoxyethyl (meth)acrylate, 2-hydroxy-3-phenoxypropyl (meth)acrylate, or other phenoxyalkyl (meth)acrylates; 2-methoxyethyl (meth)acrylate, 2-ethoxyethyl (meth)acrylate, 2-propoxyethyl (meth)acrylate, 2-butoxyethyl (meth)acrylate, 2-methoxybutyl (meth)acrylate, or other alkoxyalkyl(meth)acrylates; polyethyleneglycol mono(meth)acrylate, ethoxydiethyleneglycol (meth)acrylate, methoxypolyethyleneglycol (meth)acrylate, phenoxypolyethyleneglycol (meth)acrylate, nonylphenoxypolyethylene-glycol (meth)acrylate, polypropyleneglycol mono(meth)acrylate, methoxypolypropyleneglycol (meth)acrylate, ethoxypolypropyleneglycol (meth)acrylate, nonylphenoxypolypropyleneglycol (meth)acrylate, or other polyalkyleneglycol (meth)acrylates; cyclohexyl(meth)acrylate, 2-methylcyclohexyl(meth)acrylate, 4-butylcyclohexyl(meth)acrylate, 1-adamantyl(meth)acrylate, 2-methyl-2-adamantyl(meth)acrylate, 2-ethyl-2-adamantyl(meth)acrylate, tricyclo[5.2.1.0^{2,6}]decan-8-yl(meth)acrylate, tricyclo[5.2.1.0^{2,6}]-3-decen-8-yl(meth)acrylate, tricyclo[5.2.1.0^{2,6}]-3-decen-9-yl(meth)acrylate, bornyl(meth)acrylate, isobornyl(meth)acrylate, or other cycloalkyl(meth)acrylates; phenyl(meth)acrylate, naphthyl(meth)acrylate, biphenyl(meth)acrylate, benzyl(meth)acrylate, tetrahydrofurfuryl(meth)acrylate, 5-tetrahydrofurfuryloxycarbonylpentyl(meth)acrylate, vinyl(meth)acrylate, allyl(meth)acrylate, 2-(2-vinyloxyethoxy)ethyl(meth)acrylate, 2-[tricyclo[5.2.1.0^{2,6}]decan-8-yloxy]ethyl (meth)acrylate, 2-[tricyclo[5.2.1.0^{2,6}]-3-decen-8-yloxy]ethyl (meth)acrylate, 2-[tricyclo[5.2.1.0^{2,6}]-3-decen-9-yloxy]ethyl (meth)acrylate, γ-butyrolactone (meth)acrylate, maleimide, N-methyl maleimide, N-ethyl maleimide, N-butyl maleimide, N-cyclohexyl maleimide, N-benzyl maleimide, N-phenyl maleimide, N-(2,6-diethylphenyl)maleimide, N-(4-acetylphenyl) maleimide, N-(4-hydroxyphenyl)maleimide, N-(4-acetoxyphenyl)maleimide, N-(4-dimethylamino-3,5-dinitrophenyl)maleimide, N-(1-anilinonaphthyl-4) maleimide, N-[4-(2-benzoxazolyl)phenyl]maleimide, N-(9-acridinyl) maleimide, etc. may be mentioned.

Among these as well, methyl (meth)acrylate, butyl (meth)acrylate, cyclohexyl(meth)acrylate, 2-methylcyclohexyl(meth)acrylate, benzyl(meth)acrylate, tricyclo[5.2.1.0^{2,6}]decan-8-yl(meth)acrylate, N-phenyl maleimide, and N-cyclohexyl maleimide etc. are preferable.

The copolymerizable monomer other than acrylate is not particularly limited so long as a compound which can copolymerizae with the above monomers, but, for example, vinyl benzylmethyl ether, vinyl glycidyl ether, styrene, α-methyl styrene, vinyl toluene, indene, vinyl naphthalene, vinyl biphenyl, chloro styrene, bromo styrene, chloromethyl styrene, p-tert-butoxy styrene, p-hydroxy styrene, p-hydroxy-α-methyl styrene, p-acetoxy styrene, p-carboxy styrene, 4-hydroxyphenylvinylketone, acrylonitrile, methacrylonitrile, (meth)acrylamide, 1,2-epoxy-4-vinyl cyclohexane, isobutene, norbornene, butadiene, isoprene, or other radical polymerizable compounds may be mentioned.

These compounds may be used alone or may be used as two or more types in combination.

The method of polymerization of the above monomer may be an ordinary method. For example, the suspension polymerization method, emulsion polymerization method, solution polymerization method, etc. is employed.

Further, the resin compound (A) used in the present invention preferably further contains a resin compound (A2) which has two or more (meth)acryloyl groups in a molecule and which does not have a carboxyl group (below, suitably referred to as a “carboxyl group-free resin compound (A2)”). The carboxyl group-free resin compound (A2) should be a resin which has a weight average molecular weight of 1000 or more, which has two or more (meth)acryloyl groups in a molecule, and which does not have a carboxyl group, but, for example, a homopolymer which has two or more (meth)acryloyl groups in a molecule or a copolymer of this and a copolymerizable monomer etc. may be mentioned.

As the compound which has two or more (meth)acryloyl groups in a molecule, it is possible to use one which is similar to the above-mentioned carboxyl group-containing resin compound (A1). Among the compounds which have two or more (meth)acryloyl groups in a molecule, from the viewpoint of being able to reduce the shrinkage stress at the time of ultraviolet curing, a bifunctional or higher urethane acrylate can be preferably used. In this case, the carboxyl group-free resin compound (A2) also corresponds to the resin compound (A3) which has a urethane structure explained later.

Further, for the other copolymerizable monomers as well, ones similar to the above-mentioned carboxyl group-containing resin compound (A1) can be used.

Note that, the carboxyl group-free resin compound (A2) should be one which substantially does not contain a carboxyl group. For example, it may also contain a carboxyl group if of the extent of the amount of an impurity.

Note that, as the carboxyl group-containing resin compound (A1) and the carboxyl group-free resin compound (A2), for example, an urethane (meth)acrylate which may be modified with a carboxylic acid (may be modified with anhydrous carboxylic acid) (product name “NK Oligo UA-6HA, NK Oligo UA-53H, NK Oligo U-200PA, NK Oligo UA-4200, NK Oligo UA-122P” {above, made by Shin-Nakamura Chemical} etc.), a novolac epoxy(meth)acrylate which may be modified with a carboxylic acid (may be modified with anhydrous carboxylic acid) (product name “NK Oligo EA-1020, NK Oligo EA-1025, NK Oligo EA-1026, NK Oligo EA-1028, NK Oligo EA-6320, NK Oligo EA-6340, NK Oligo EA-7140” {above, made by Shin-Nakamura Chemical} etc.) etc. may be used. Note that, the above-mentioned urethane (meth)acrylate which may be modified with a carboxylic acid (may be modified with anhydrous carboxylic acid) is a carboxyl group-free resin compound (A2) and is also a resin compound which corresponds to the later mentioned urethane structure-containing resin compound (A3).

Further, in the present invention, in addition to the carboxyl group-containing resin compound (A1), a resin compound which has two or more (meth)acryloyl groups in a molecule and which has a urethane structure (A3) (below, suitably referred to as a “urethane structure-containing resin compound (A3)”) may also be contained. The urethane structure-containing resin compound (A3) is not particularly limited so long as a resin which has a weight average molecular weight of 1000 or more, which has two or more (meth)acryloyl groups in a molecule, and which has a urethane structure.

Note that, when using a urethane structure-containing resin compound (A3), it is possible to use it together with the carboxyl group-free resin compound (A2). Alternatively, as the monomer for forming the carboxyl group-free resin compound (A2), it is possible to use a bifunctional or higher urethane acrylate so that the carboxyl group-free resin compound (A2) may also be made one which corresponds to the urethane structure-containing resin compound (A3). That is, it is also possible to use a resin which has a weight average molecular weight of 1000 or more, which has two or more (meth)acryloyl groups in a molecule, which does not contain a carboxyl group, and which has a urethane structure (A2/A3).

In the present invention, as the carboxyl group-containing resin compound (A1), carboxyl group-free resin compound (A2), and urethane structure-containing resin compound (A3), from the viewpoint of the alkali solubility, ones which have acidic groups are preferable. The “acidic group” means a substituent which can function as a Lewis acid, that is, a substituent which has the property of enabling electron pairs to be held in the ionized state. As specific examples of this acidic group, a carboxyl group, hydroxyl group, aldehyde group, sulfonic acid group, phosphoric acid group, etc. may be mentioned.

The carboxyl group-containing resin compound (A1), carboxyl group-free resin compound (A2), and urethane structure-containing resin compound (A3) have a weight average molecular weight of 1000 or more. The upper limit is not particularly limited, but is usually 5000 or less, while 3500 or less is preferable. Further, regarding the ratio of content of the carboxyl group-containing resin compound (A1) and the carboxyl group-free resin compound (A2), the content of the carboxyl group-free resin compound (A2) is preferably over 10 parts by weight to less than 50 parts by weight with respect to 70 parts by weight of the carboxyl group-containing resin compound (A1), more preferably over 10 parts by weight to 30 parts by weight. If the ratio of content of the carboxyl group-free resin compound (A2) is too great, the effect of suppression of peeling at the time of development becomes lower. On the other hand, if the ratio of content is too small, the surface of the obtained resin film easily becomes rough and the various properties are liable to decline.

((Meth)acryloyl Compound (B))

The (meth)acryloyl compound (B) used in the present invention is a compound which has a weight average molecular weight of less than 1000 and which has two or more (meth)acryloyl groups in a molecule.

The (meth)acryloyl compound (B) should be a compound which has a weight average molecular weight of less than 1000 and which has two or more (meth)acryloyl groups in a molecule, but, for example, a (meth)acrylic acid ester which has two or more (meth)acryloyl groups in a molecule may be mentioned. Further, the (meth)acryloyl compound (B) should be a compound which has two or more (meth)acryloyl groups in a molecule, but it may also be one which has a carboxyl group in the molecule. Alternatively, it may be one which does have such a carboxyl group.

As the (meth)acrylic acid ester which has two or more (meth)acryloyl groups in a molecule, ethyleneglycol dimethacrylate, diethyleneglycol dimethacrylate, triethyleneglycol dimethacrylate, tricyclodecane dimethanol di(meth)acrylate, neopentylglycol dimethacrylate, 1,6-hexanediol di(meth)acrylate, pentaerythritol triacrylate, trimethylolpropane tri(meth)acrylate, pentaerythritol tetraacrylate, dipentaerythritol pentaacrylate, dipentaerythritol hexaacrylate, ethoxylated isocyanulic triacrylate, ethoxylated glycerin triacrylate, tris(2-acryloyloxyethyl)isocyanulate, bis(2-acryloyloxyethyl)(2-hydroxyethyl)isocyanulate, etc. may be mentioned.

Further, the (meth)acryloyl compound (B) may be a homopolymer of the above-mentioned (meth)acrylic acid ester which has two or more (meth)acryloyl groups in a molecule and a copolymer of this and another copolymerizable monomer. As such a monomer, a (meth)acrylic acid ester which has one (meth)acryloyl group in a molecule, (meth)acrylic acid, aromatic vinyl compound, vinyl ester-based compound, vinyl ether-based compound, vinyl ketone-based compound, epoxy group-containing vinyl compound, etc. may be mentioned.

As specific examples of the (meth)acrylic acid ester which has one (meth)acryloyl group in a molecule, methyl (meth)acrylate, ethyl (meth)acrylate, n-propyl(meth)acrylate, glycidyl(meth)acrylate, 2-hydroxyethyl(meth)acrylate, 2-isocyanate ethyl (meth)acrylate, isobornyl(meth)acrylate, 2-hydroxy-3-phenoxypropyl acrylate, 3,4-epoxycyclohexyl methyl methacrylate, (3-methyl-3-oxetanyl)methyl acrylate, etc. may be mentioned.

As the aromatic vinyl compound, styrene, α-methylstyrene, vinyl toluene, 2,4-dimethyl styrene, ethyl styrene, isopropyl styrene, butyl styrene, phenyl styrene, cyclohexyl styrene, benzyl styrene, crotyl benzene, vinyl naphthalene, etc. may be mentioned.

As the vinyl ester-based compound, vinyl acetate, vinyl butylate, vinyl propionate, vinyl caprolate, divinyl adipate, vinyl benzoate, etc. may be mentioned.

As the vinyl ether-based compound, vinyl methyl ether, vinyl ethyl ether, vinyl propyl ether, vinyl butyl ether, 1,4-butanediol divinyl ether, diethyleneglycol divinyl ether, cyclohexane dimethanol divinyl ether, etc. may be mentioned.

As the vinyl ketone-based compound, vinyl methyl ketone, vinyl ethyl ketone, vinyl phenyl ketone, etc. may be mentioned.

As the epoxy group-containing vinyl compound, 1,2-epoxy-5-hexene, 1,2-epoxy-7-octene, 1,2-epoxy-9-decene, 8-hydroxy-6,7-epoxy-1-octene, etc. may be mentioned.

These (meth)acryloyl compounds (B) may be used alone or as two or more types combined. The (meth)acryloyl compound (B) has a weight average molecular weight of less than 1000, preferably 750 or less, more preferably 600 or less.

The content of the (meth)acryloyl compound (B) in the negative type photosensitive resin composition of the present invention is preferably 1 to 200 parts by weight with respect to 100 parts by weight of the resin compound (A), more preferably 10 to 180 parts by weight, furthermore preferably 20 to 150 parts by weight. By making the content of the (meth)acryloyl compound (B) in the above range, it is possible to make it good in film formability while effectively preventing the formation of residue at the time of development.

(Silane-Modified Resin (C))

The silane-modified resin (C) used in the present invention has a resin part and silane compound part in a state with these chemically bonded with each other.

The material which forms the resin part of the silane-modified resin (C) is not particularly limited, but a polymer material which has a functional group which can chemically bond with the silane compound part is preferable. Such a polymer material is not particularly limited, but, for example, a polyester, polyamide, polyimide, polyamic acid, epoxy resin, acrylic resin, urethane resin, phenol resin, etc. may be mentioned. Among these as well, from the viewpoint of the effects of the present invention becoming much more remarkable, a polyamic acid, epoxy resin, acrylic resin, or phenol resin is preferable. Further, the functional group which can bond with the silane compound part is not particularly limited, but, for example, a hydroxyl group, amino group, thiol group, carboxylic acid group, acid anhydride group, epoxy group, amide group, imide group, etc. may be mentioned. From the viewpoint of the reactivity with the silane compound part, a hydroxyl group, carboxylic acid group, or acid anhydride group is preferable.

The silicon compound which forms the silane compound part of the silane-modified resin (C) is not particularly limited, but, for example, a silicon compound of the following formula (1) and/or a partially hydrolyzed condensate of a silicon compound of the following formula (1) may be mentioned. From the viewpoint of the effects of the present invention becoming much more remarkable, in particular, a silicon compound of the following formula (2) which can be obtained by partial hydrolysis of the silicon compound of formula (1) is preferable.

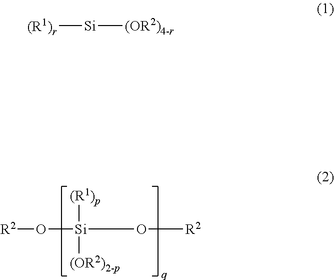

In the above formula (1), “r” is an integer of 0 to 3. R¹ is a C₁ to C₁₀ alkyl group which may have a functional group which is directly bonded to a carbon atom, C₆ to C₂₀ aryl group, or C₂ to C₁₀ unsaturated aliphatic group, where when R¹ is a plurality, the plurality of R¹ may be the same or different. Further, when R² is a hydrogen atom or a C₁ to C₁₀ alkyl group which may have a functional group which is directly bonded to a carbon atom and R² is a plurality, the plurality of R² may be the same or different. Further, as the functional group which forms R¹ and R² and which is directly bonded to a carbon atom, a hydroxyl group, epoxy group, halogen group, mercapto group, carboxyl group, and methacryloxy group may be mentioned.

Further, in the above formula (2), “p” is 0 or 1. “q” is an integer of 2 to 10, while R¹ and R² are similar to the above formula (1).

As specific examples of the C₁ to C₁₀ alkyl group which forms R¹ and R² and which may have a functional group which is directly bonded to a carbon atom, a methyl group, ethyl group, n-propyl group, i-propyl group, n-butyl group, i-butyl group, sec-butyl group, t-butyl group, n-pentyl group, i-pentyl group, sec-pentyl group, n-hexyl group, i-hexyl group, sec-hexyl group, cyclopentyl group, cyclohexyl group, cycloheptyl group, 3-chloropropyl group, 3-glycidoxypropyl group, epoxypropyl group, 3-methacryloxypropyl group, 3-mercaptopropyl group, 3,3,3-trifluoropropyl group, etc. may be mentioned.

As specific examples of the C₆ to C₂₀ aryl group which forms R¹ and which may have a functional group which is directly bonded to a carbon atom, a phenyl group, toluoyl group, p-hydroxyphenyl group, 1-(p-hydroxyphenyl)ethyl group, 2-(p-hydroxyphenyl)ethyl group, 4-hydroxy-5-(p-hydroxyphenylcarbonyloxy)pentyl group, naphthyl group, etc. may be mentioned.

Further, as specific examples of a C₁ to C₁₀ unsaturated aliphatic group which forms R¹ and which may have a functional group which is directly bonded to a carbon atom, a vinyl group, 3-acryloxypropyl group, 3-methacryloxypropyl group, etc. may be mentioned.

As specific examples of such a silicon compound, tetramethoxysilane, tetraethoxysilane, tetrapropoxysilane, tetra-i-propoxysilane, tetrabutoxysilane, tetra-1-butoxysilane, methyl trimethoxysilane, ethyl trimethoxysilane, n-propyl trimethoxysilane, propyl trimethoxysilane, 3-chloropropyl trimethoxysilane, vinyl trimethoxysilane, phenyl trimethoxysilane, methyltriethoxysilane, ethyl triethoxysilane, n-propyl triethoxysilane, i-propyl triethoxysilane, 3-chloropropyl triethoxysilane, vinyl triethoxysilane, phenyl triethoxysilane, methyl tri-i-propoxysilane, ethyl tri-i-propoxysilane, n-propyl tri-i-propoxysilane, i-propyl tri-i-propoxysilane, 3-chloropropyl tri-i-propoxysilane, vinyl tri-i-propoxysilane, phenyl tri-i-propoxysilane, methyl tributoxysilane, ethyl tributoxysilane, n-propyl tributoxysilane, i-propyl tributoxysilane, 3-chloropropyl tributoxysilane, vinyl tributoxysilane, phenyl tributoxysilane, 3,3,3-trifluoro trimethoxysilane, 3-methacryloxypropyl trimethoxysilane, methyl triglycidoxysilane, 3-glycidoxypropyl trimethoxysilane, 3-mercaptopropyl trimethoxysilane, 3,4-epoxycyclohexyl trimethoxysilane, 3,3,3-trifluoro triethoxysilane, 3-methacryloxypropyl triethoxysilane, 3-glycidoxypropyl triethoxysilane, 3-mercaptopropyl triethoxysilane, 3,4-epoxycyclohexyl triethoxysilane, 3,3,3-trifluoro tri-i-propoxysilane, 3-methacryloxypropyl tri-i-propoxysilane, 3-glycidoxypropyl tri-i-propoxysilane, 3-mercaptopropyl tri-i-propoxysilane, 3,4-epoxycyclohexyl tri-i-propoxysilane, 3,3,3-trifluoro tributoxysilane, 3-methacryloxypropyl tributoxysilane, 3-glycidoxypropyl tributoxysilane, 3-mercaptopropyl tributoxysilane, 3,4-epoxycyclohexyl tributoxysilane, dimethyl dimethoxysilane, dimethyl diethoxysilane, diethyl dimethoxysilane, diethyl diethoxysilane, diphenyl dimethoxysilane, diphenyl diethoxysilane, etc. may be mentioned. These are preferably used as partially hydrolyzed condensates. These may be used as single types alone or two or more types together.

Further, when the silane compound part is a partially hydrolyzed condensate of a silicon compound, the partial condensate which is obtained by partial hydrolysis of the above-mentioned silicon compound may be used as it is. Alternatively, the obtained partial condensate which is substituted in part by a dealcoholization reaction using an alcohol which has an epoxy group, halogen group, mercapto group, carboxyl group, methacryloxy group, or other functional group may be used. By substitution of the partial condensate which is obtained by partial hydrolysis of the above-mentioned silicon compound by using an alcohol which has such a functional group, it is possible to simply obtain a partial hydrolyzed condensate which has such a functional group.

The method of chemically bonding the above-mentioned resin part and silane compound part to obtain the silane-modified resin (C) is not particularly limited, but, for example, the method of using a polymer material which has a hydroxyl group for the resin part and reacting this with the alkoxyl group of the silane compound part for dealcoholization so as to make the resin part and the silane compound part chemically bond may be mentioned. Alternatively, the method of using a polymer material which has a carboxylic acid group or an acid anhydride group for the resin part, using a compound which has a glycidyloxy group for the silane compound part, and reacting these by an addition reaction, the method of opening the oxirane ring to cause a ring-opening esterification reaction, etc. may be mentioned. Further, by making the resin part and the silane compound part chemically bond, then polymerizing the resin part, it is possible to render the resin part higher in molecular weight. Note that, in this case, the method may be employed of using a low molecular weight organic material as the material for chemical bonding with the silane compound part, making the low molecular weight organic material and silane compound parts chemically bond, then polymerizing the low molecular weight organic material to render it higher in molecular weight.

For example, in the above method, according to the dealcoholization reaction, the material which forms the resin part and the material which forms the silane compound part can be charged and heated and a transesterification reaction can be performed while distilling off the formed alcohol so as to obtain the silane-modified resin (C). The reaction temperature is usually 70 to 150° C., preferably 80 to 130° C., while the overall reaction time is usually 2 to 15 hours. If the reaction temperature is too low, it is not possible to efficiently distill off the alcohol, while if the reaction temperature is too high, sometimes curing and condensation of the material which forms the silane compound part end up starting.

Further, at the time of the above dealcoholization reaction, to promote the reaction, it is possible to use a conventionally known transesterification catalyst of ester and hydroxyl group. As the transesterification catalyst, for example, acetic acid, p-toluene sulfonic acid, benzoic acid, propionic acid, and other organic acids and lithium, sodium, potassium, rubidium, cesium, magnesium, calcium, barium, strontium, zinc, aluminum, titanium, cobalt, germanium, tin, lead, antimony, arsenic, cerium, boron, cadmium, manganese, and other such metals and their oxides, organic acid salts, halides, alkoxides, etc. may be mentioned. Among these, it is preferable to use an organic acid salt of a metal and organic acid. In particular, organotin and an organic acid salt of tin are preferable. Specifically, acetic acid, tin octylate, and dibutyltin dilaurate are preferable.

Further, the dealcoholization reaction can be performed in an organic solvent or without a solvent. The organic solvent is not particularly limited so long as an organic solvent which dissolves the material which forms the resin part and the material which forms the silane compound part, but, for example, dimethylformamide, dimethylacetoamide, methylethylketone, cyclohexanone, diethyleneglycol methylethyl ether, and other aprotonic polar solvents which have a boiling point of 75° C. or more is preferably used.

Alternatively, in the above method, according to the ring-opening esterification reaction, the material which forms the resin part and the material which forms the silane compound part can be charged and heated to cause a ring-opening esterification reaction and thereby obtain the silane-modified resin (C). The reaction temperature is usually 40 to 130° C., preferably 70 to 110° C., while the total reaction time is usually 1 to 7 hours. If the reaction temperature is too low, the reaction time becomes long. Further, if the reaction temperature is too high, sometimes curing and condensation of the material which forms the silane compound part end up being started.

In the ring-opening esterification reaction, it is possible to use a catalyst for promoting a reaction. As the catalyst, for example, 1,8-diaza-bicyclo[5.4.0]-7-undecene, triethylenediamine, benzyldimethylamine, triethanolamine, dimethylaminoethanol, tris(dimethylaminomethyl)phenol, or other tertiary amines; 2-methylimidazole, 2-phenylimidazole, 2-phenyl-4-methylimidazole, 2-heptadecylimidazole, benzimidazole, or other imidazoles; tributylphosphine, methyldiphenylphosphine, triphenylphosphine, diphenylphosphine, phenylphosphine, or other organic phosphines; tetraphenylphosphonium tetraphenyl borate, 2-ethyl-4-methylimidazole tetraphenyl borate, N-methylmorpholine tetraphenyl borate, or other tetraphenyl borates etc. may be mentioned.

Further, the ring-opening esterification reaction is preferably performed in the presence of an organic solvent. The organic solvent is not particularly limited so long as an organic solvent which dissolves the material which forms the resin part and the material which forms the silane compound part, but, for example, N-methyl-2-pyrrolidone, dimethylformamide, dimethylacetoamide, cyclohexanone, etc. may be used.

The ratio between the resin part and silane compound part of the silane-modified resin (C) used in the present invention, by weight ratio of “resin part:silane compound part”, is preferably 1:50 to 50:1, more preferably 1:10 to 10:1. By making the ratio of the resin part and the silane compound part in the above range, the effects of the present invention become more remarkable, so this is preferred.

The content of the silane-modified resin (C) in the negative type photosensitive resin composition of the present invention is preferably 1 to 100 parts by weight with respect to 100 parts by weight with respect to the resin compound (A), more preferably 2 to 50 parts by weight, furthermore preferably 5 to 40 parts by weight. By making the content of the silane-modified resin (C) in the above range, it is possible to make the pattern-forming ability by development, in particular, the adhesion of the developed patterns when making the width of the developed patterns finer and the shape of the holes at the time of baking, particularly good.

(Radical-Generating Type Photopolymerization Initiator (D))

The radical-generating type photopolymerization initiator (D) used in the present invention is not particularly limited so long as a compound which generates radicals by the irradiation of light so as to cause a chemical reaction, but preferably has a sensitivity to light of a wavelength of 400 nm or less and generates radicals and causes a chemical reaction when irradiated by light of a wavelength of 400 nm or less, specifically ultraviolet light or electron beams or other rays.

As specific examples of the radical-generating type photopolymerization initiator (D), benzophenone, methyl o-benzoyl benzoate, 4,4-bis(dimethylamine)benzophenone, 4,4-bis(diethylamine)benzophenone, α-amino-acetophenone, 4,4-dichlorobenzophenone, 4-benzoyl-4-methyldiphenylketone, dibenzylketone, fluorenone, 2,2-diethoxyacetophenone, 2,2-dimethoxy-2-phenylacetophenone, 2-hydroxy-2-methylpropiophenone, p-tert-butyldichloroacetophenone, thioxanthone, 2-methylthioxanthone, 2-chlorothioxanthone, 2-isopropylthioxanthone, diethylthioxanthone, benzyldimethylketal, benzylmethoxyethylacetal, benzoinmethyl ether, benzoinbutyl ether, anthraquinone, 2-tert-butylanthraquinone, 2-amylanthraquinone, β-chloroanthraquinone, anthrone, benzanthrone, dibenzosuberone, methylenanthrone, 4-azidobenzylacetophenone, 2,6-bis(p-azidobenzylidene)cyclohexane, 2,6-bis(p-azidobenzylidene)-4-methylcyclohexanone, 2-phenyl-1,2-butadion-2-(o-methoxycarbonyl)oxime, 1-phenyl-propanedion-2-(o-ethoxycarbonyl) oxime, 1,3-diphenyl-propanetrion-2-(o-ethoxycarbonyl)oxime, 1-phenyl-3-ethoxy-propanetrion-2-(o-benzoyl)oxime, Michler ketone, 2-methyl-1[4-(methylthio)phenyl]-2-morpholinopropan-1-one, 2-benzyl-2-dimethylamino-1-(4-morpholinophenyl)-butanone, naphthalenesulfonyl chloride, quinolinesulfonyl chloride, n-phenylthioacrylidone, 4,4-azobisisobutyronitrile, diphenyl disulfide, benzothiazole disulfide, triphenylphosphine, camphorquinone, N,N-octamethylenebisacridine, 2-(dimethylamino)-2-[(4-methylphenyl)methyl]-1-[4-(4-morpholinyl)phenyl]-1-butanone (made by BASF, Irgacure 379EG), 1,7-bis(9-acridyl)-heptane (made by ADEKA, N1717), [1-(4-phenylsulfanylbenzoyl) heptylideneamino]benzoate (made by BASF, OXE-01), ethanone,1-[9-ethyl-6-(2-methylbenzoyl)-9H-carbazol-3-yl]-,1-(o-acetyloxime) (made by BASF, OXE-02), carbon tetrachloride, tribromophenylsulfone, benzoin peroxide, eosin, methylene blue, or other photoreducible dyes and ascorbic acid or triethanolamine or other such reducing agent in combination etc. may be mentioned.

Among these as well, [1-(4-phenylsulfanylbenzoyl) heptylidenamino]benzoate is preferable. These radical-generating type photopolymerization initiators (D) can be used alone or as two or more types combined.

In the negative type photosensitive resin composition of the present invention, the content of the radical-generating type photopolymerization initiator (D) is preferably 1 to 30 parts by weight with respect to 100 parts by weight of the resin compound (A), more preferably 3 to 20 parts by weight. By making the content of the radical-generating type photopolymerization initiator (D) in the above range, it is possible to make the film-forming ability excellent while effectively preventing the production of residue at the time of development.

(Silicon Atom-Free Epoxy Group-Containing Cross-Linking Agent (E))

The silicon atom-free epoxy group-containing cross-linking agent (E) used in the present invention (below, simply referred to as an “epoxy group-containing cross-linking agent (E)”) is not particularly limited so long as one which does not have a silicon atom and which has an epoxy group as a reactive group.

The molecular weight of the epoxy group-containing cross-linking agent (E) is not particularly limited, but is preferably 200 to 550, more preferably 250 to 500, furthermore preferably 300 to 450. By using as the epoxy group-containing cross-linking agent (E) one with a molecular weight in the above range, it is possible to make the pattern-forming ability by development, in particular, the adhesion of the developed patterns when making the width of developed patterns finer and the shape of the holes at the time of baking, particularly excellent.

Further, the epoxy group-containing cross-linking agent (E) used in the present invention should be one in which no silicon atom is contained in the molecular structure and substantially no silicon atom is contained. For example, so long as an amount which can be judged as an amount of an impurity, it may be one which contains a silicon atom.

As the epoxy group-containing cross-linking agent (E), for example, a bisphenol A type epoxy resin, bisphenol F type epoxy resin, phenol novolac type epoxy resin, cresol novolac type epoxy resin, polyphenol type epoxy resin, cyclic aliphatic epoxy resin, glycidyl ether compound, epoxy acrylate polymer, etc. may be mentioned.

As specific examples of the epoxy group-containing cross-linking agent (E), a trifunctional epoxy compound which has dicyclopentadiene as a backbone (product name “XD-1000”, made by Nippon Kayaku), epoxylated 3-cyclohexene-1,2-dicarboxylic acid bis(3-cyclohexenylmethyl)-modified ε-caprolactone (aliphatic cyclic trifunctional epoxy resin, product name “Epolead GT301”, made by Daicel Corporation), epoxylated butane tetracarboxylic acid tetrakis(3-cyclohexenylmethyl)-modified ε-caprolactone (aliphatic cyclic tetrafunctional epoxy resin, product name “Epolead GT401”, made by Daicel Corporation), 3,4-epoxycyclohexenylmethyl-3′,4′-epoxycyclohexenecarboxylate (product name “Celloxide 2021”, made by Daicel Corporation), 1,2:8,9-diepoxylimonene (product name “Celloxide 3000”, made by Daicel Corporation), or other epoxy compound which has an alicyclic structure;

an aromatic amine type polyfunctional epoxy compound (product name “H-434”, made by Tohto Kasei), tris(2,3-epoxypropyl)isocyanulate (polyfunctional epoxy compound which has a triazine backbone, product name “TEPIC”, made by Nissan Chemical Industries), cresol novolac type polyfunctional epoxy compound (product name “EOCN-1020”, made by Nippon Kayaku), phenol novolac type polyfunctional epoxy compound (Epicoat 152, 154, made by Japan Epoxy Resin), polyfunctional epoxy compound which has a naphthalene backbone (product name “EXA-4700”, made by DIC), chain alkyl polyfunctional epoxy compound (product name “SR-TMP”, made by Sakamoto Yakuhin Kogyo), polyfunctional epoxypolybutadiene (product name “Epolead PB3600”, made by Daicel Corporation), polyethyleneglycol diglycidyl ether (product name “Denacol EX850”, made by Nagase ChemteX Corporation), glycidylpolyether compound of glycerin (product name “SR-GLG”, made by Sakamoto Yakuhin Kogyo), diglycerin polyglycidylether compound (product name “SR-DGE”, made by Sakamoto Yakuhin Kogyo), sorbitol-based polyglycidylether compound (product name “SR-SEP”, made by Sakamoto Yakuhin Kogyo), polyglycerin polyglycidylether compound (product name “SR-4GL”, made by Sakamoto Yakuhin Kogyo), or other epoxy compound which does not have an alicyclic structure may be mentioned.

Among these as well, from the viewpoint of the adhesion of the obtained resin film, diethyleneglycol diglycidylether, a glycidyl polyether compound of glycerin, a diglycerin polyglycidylether compound, a sorbitol-based polyglycidylether compound, polyglycerin polyglycidylether compound, and other glycidylether compounds are preferable.

In the negative type photosensitive resin composition of the present invention, the content of the epoxy group-containing cross-linking agent (E) is not particularly limited. It may be freely set considering the extent of the heat resistance which is sought from the resin film obtained using the negative type photosensitive resin composition of the present invention, but is preferably 30 to 150 parts by weight with respect to 100 parts by weight of the resin compound (A), more preferably 40 to 120 parts by weight, furthermore preferably 50 to 100 parts by weight. By making the content of the epoxy group-containing cross-linking agent (E) in the above range, it is possible to improve the heat resistance when made into a resin film.

(Other Compounding Agents)

The negative type photosensitive resin composition of the present invention may further contain a solvent. The solvent is not particularly limited. A solvent which is known as one for a negative type photosensitive resin composition, for example, acetone, methylethylketone, cyclopentanone, 2-hexanone, 3-hexanone, 2-heptanone, 3-heptanone, 4-heptanone, 2-octanone, 3-octanone, 4-octanone, and other linear ketones; n-propyl alcohol, isopropyl alcohol, n-butyl alcohol, cyclohexanol, and other alcohols; ethyleneglycol dimethyl ether, ethyleneglycol diethyl ether, dioxane, and other ethers; ethyleneglycol monomethyl ether, ethyleneglycol monoethyl ether, and other alcohol ethers; propyl formate, butyl formate, propyl acetate, butyl acetate, methyl propionate, ethyl propionate, methyl butyrate, ethyl butyrate, methyl lactate, ethyl lactate, and other esters; cellosolve acetate, methyl cellosolve acetate, ethyl cellosolve acetate, propylcellusolve acetate, butylcellosolve acetate, and other cellosolve esters; propyleneglycol, propyleneglycol monomethylether, propyleneglycol monomethylether acetate, propyleneglycol monoethylether acetate, propyleneglycol monobutylether, and other propyleneglycols; diethyleneglycol monomethylether, diethyleneglycol monoethylether, diethyleneglycol dimethylether, diethyleneglycol diethylether, diethyleneglycol methylethylether, and other diethyleneglycols; γ-butyrolactone, γ-valerolactone, γ-caprolactone, γ-caprylolactone, and other saturated γ-lactones; trichloroethylene and other halogenated hydrocarbons; toluene, xylene, and other aromatic hydrocarbons; dimethylacetoamide, dimethylformamide, N-methylacetoamide, and other polar solvents etc. may be mentioned. These solvents may be used alone or as two or more types in combination. The content of the solvent is preferably 10 to 10000 parts by weight with respect to 100 parts by weight of the resin compound (A), more preferably 50 to 5000 parts by weight, furthermore preferably 100 to 1000 parts by weight in range. Note that, when the resin composition is made to include a solvent, the solvent is usually removed after formation of the resin film.

Further, the negative type photosensitive resin composition of the present invention may further contain a compound which has an acidic group or thermally latent acidic group. The compound which has an acidic group or thermally latent acidic group is not particularly limited so long as it has an acidic group or a thermally latent acidic group which forms an acidic group upon heating. Preferably it is an aliphatic compound, aromatic compound, or heterocyclic compound, more preferably an aromatic compound or heterocyclic compound.

These compounds which have an acidic group or thermally latent acidic group may be used alone or as two or more types combined.

The number of the acidic groups or thermally latent acidic groups of the compound which has an acidic group or thermally latent acidic group is not particularly limited, but a total of two or more acidic groups and/or thermally latent acidic groups is preferable. The acidic groups or thermally latent acidic groups may be the same or different from each other.

The acidic group should be an acidic functional group. As specific examples, sulfonic acid groups, phosphoric acid groups, or other strongly acidic groups; carboxy groups, thiol groups, carboxymethylenethio groups, or other weakly acidic groups; may be mentioned. Among these as well, a carboxy group, thiol group, or carboxymethylenethio group is preferable, while a carboxy group is particularly preferable. Further, among these acidic groups as well, ones with acid dissociation constants pKa in the range of 3.5 to 5.0 are preferable. Note that, when there are two or more acidic groups, the first dissociation constant pKa1 is made the acid dissociation constant, and the first dissociation constant pKa1 is preferably in the above range. Further, pKa is found by measuring the acid dissociation constant Ka=[H₃O⁺][B⁻]/[BH] under dilute aqueous solution conditions and processing by pKa=−logKa. Here, BH indicates the organic acid, while B⁻ indicates the conjugated base of the organic acid.

Note that, the method of measurement of pKa can, for example, be use of a pH meter for measurement of the concentration of hydrogen ions and calculation from the concentration of the substance and the concentration of the hydrogen ions.

Further, the thermally latent acidic group may be a group which produces an acidic functional group upon being heated. As specific examples, a sulfonium salt group, benzothiazolium salt group, amonium salt group, phosphonium salt group, block carboxylic acid group, etc. may be mentioned. Among these, a block carboxylic acid group is preferable. Note that, the blocking agent of the carboxy group which is used for obtaining a block carboxylic acid group is not particularly limited, but a vinyl ether compound is preferable.

Further, the compound which has an acidic group or a thermally latent acidic group may have a substituent group other than an acidic group or a thermally latent acidic group.

As such a substituent group, in addition to an alkyl group, aryl group, or other hydrocarbon group, a halogen atom; alkoxy group, aryloxy group, acyloxy group, heterocyclic oxy group; amino group which is substituted by an alkyl group or aryl group or heterocyclic group, acylamino group, ureido group, sulfamoylamino group, alkoxycarbonylamino group, or aryloxycarbonylamino group; alkylthio group, arylthio group, heterocyclic thio group; or other polar group which does not have a proton, hydrocarbon group which is substituted by a polar group which does not have a proton, etc. may be mentioned.

Among the compounds which have such an acidic group or thermally latent acidic group, as specific examples of a compound which has an acidic group, methane acid, ethane acid, propane acid, butane acid, pentane acid, butane acid, pentane acid, hexane acid, heptane acid, octane acid, nonane acid, decane acid, glycol acid, glycerin acid, ethane diacid (also referred to as “oxalic acid”), propane diacid (also referred to as “malonic acid”), butane diacid (also referred to as “succinic acid”), pentane diacid, hexane diacid (also referred to as “adipic acid”), 1,2-cyclohexane dicarboxylic acid, 2-oxopropanic acid, 2-hydroxybutane diacid, 2-hydroxy propanetricarboxylic acid, mercaptosuccinic acid, dimercaptosuccinic acid, 2,3-dimercapto-1-propanol, 1,2,3-trimercaptopropane, 2,3,4-trimercapto-1-butanol, 2,4-dimercapto-1,3-butanediol, 1,3,4-trimercapto-2-butanol, 3,4-dimercapto-1,2-butanediol, 1,5-dimercapto-3-thiapentane, or other aliphatic compound;

benzoic acid, p-hydroxybenzenecarboxylic acid, o-hydroxybenzenecarboxylic acid, 2-naphthalenecarboxylic acid, methylbenzoic acid, dimethylbenzoic acid, trimethylbenzoic acid, 3-phenylpropane acid, dihydroxybenzoic acid, dimethoxybenzoic acid, benzene-1,2-dicarboxylic acid (also referred to as “phthalic acid”), benzene-1,3-dicarboxylic acid (also referred to as “isophthalic acid”), benzene-1,4-dicarboxylic acid (also referred to as “terephthalic acid”), benzene-1,2,3-tricarboxylic acid, benzene-1,2,4-tricarboxylic acid, benzene-1,3,5-tricarboxylic acid, benzenehexacarboxylic acid, biphenyl-2,2′-dicarboxylic acid, 2-(carboxymethyl)benzoic acid, 3-(carboxymethyl)benzoic acid, 4-(carboxymethyl)benzoic acid, 2-(carboxycarbonyl)benzoic acid, 3-(carboxycarbonyl)benzoic acid, 4-(carboxycarbonyl)benzoic acid, 2-mercaptobenzoic acid, 4-mercaptobenzoic acid, diphenol acid, 2-mercapto-6-naphthalenecarboxylic acid, 2-mercapto-7-naphthalenecarboxylic acid, 1,2-dimercaptobenzene, 1,3-dimercaptobenzene, 1,4-dimercaptobenzene, 1,4-naphthalenedithiol, 1,5-naphthalenedithiol, 2,6-naphthalenedithiol, 2,7-naphthalenedithiol, 1,2,3-trimercaptobenzene, 1,2,4-trimercaptobenzene, 1,3,5-trimercaptobenzene, 1,2,3-tris(mercaptomethyl)benzene, 1,2,4-tris(mercaptomethyl)benzene, 1,3,5-tris(mercaptomethyl)benzene, 1,2,3-tris(mercaptoethyl)benzene, 1,2,4-tris(mercaptoethyl)benzene, 1,3,5-tris(mercaptoethyl)benzene, or other aromatic compound;

nicotinic acid, isonicotinic acid, 2-furoic acid, pyrrole-2,3-dicarboxylic acid, pyrrole-2,4-dicarboxylic acid, pyrrole-2,5-dicarboxylic acid, pyrrole-3,4-dicarboxylic acid, imidazole-2,4-dicarboxylic acid, imidazole-2,5-dicarboxylic acid, imidazole-4,5-dicarboxylic acid, pyrazole-3,4-dicarboxylic acid, pyrazole-3,5-dicarboxylic acid, or other five-member heterocyclic compound which contains nitrogen atoms; thiophen-2,3-dicarboxylic acid, thiophen-2,4-dicarboxylic acid, thiophen-2,5-dicarboxylic acid, thiophen-3,4-dicarboxylic acid, thiazole-2,4-dicarboxylic acid, thiazole-2,5-dicarboxylic acid, thiazole-4,5-dicarboxylic acid, isothiazole-3,4-dicarboxylic acid, isothiazole-3,5-dicarboxylic acid, 1,2,4-thiadiazole-2,5-dicarboxylic acid, 1,3,4-thiadiazole-2,5-dicarboxylic acid, 3-amino-5-mercapto-1,2,4-thiadiazole, 2-amino-5-mercapto-1,3,4-thiadiazole, 3,5-dimercapto-1,2,4-thiadiazole, 2,5-dimercapto-1,3,4-thiadiazole, 3-(5-mercapto-1,2,4-thiadiazol-3-ylsulfanyl)succinic acid, 2-(5-mercapto-1,3,4-thiadiazol-2-ylsulfanyl)succinic acid, (5-mercapto-1,2,4-thiadiazol-3-ylthio)acetic acid, (5-mercapto-1,3,4-thiadiazol-2-ylthio)acetic acid, 3-(5-mercapto-1,2,4-thiadiazol-3-ylthio)propionic acid, 2-(5-mercapto-1,3,4-thiadiazol-2-ylthio)propionic acid, 3-(5-mercapto-1,2,4-thiadiazol-3-ylthio)succinic acid, 2-(5-mercapto-1,3,4-thiadiazol-2-ylthio)succinic acid, 4-(3-mercapto-1,2,4-thiadiazol-5-yl)thiobutanesulfonic acid, 4-(2-mercapto-1,3,4-thiadiazol-5-yl)thiobutanesulfonic acid, or other five-member heterocyclic compound which contains nitrogen atoms and sulfur atoms;

pyridine-2,3-dicarboxylic acid, pyridine-2,4-dicarboxylic acid, pyridine-2,5-dicarboxylic acid, pyridine-2,6-dicarboxylic acid, pyridine-3,4-dicarboxylic acid, pyridine-3,5-dicarboxylic acid, pyridazine-3,4-dicarboxylic acid, pyridazine-3,5-dicarboxylic acid, pyridazine-3,6-dicarboxylic acid, pyridazine-4,5-dicarboxylic acid, pyrimidine-2,4-dicarboxylic acid, pyrimidine-2,5-dicarboxylic acid, pyrimidine-4,5-dicarboxylic acid, pyrimidine-4,6-dicarboxylic acid, pyradine-2,3-dicarboxylic acid, pyradine-2,5-dicarboxylic acid, pyridine-2,6-dicarboxylic acid, triazine-2,4-dicarboxylic acid, 2-diethylamino-4,6-dimercapto-s-triazine, 2-dipropylamino-4,6-dimercapto-s-triazine, 2-dibutylamino-4,6-dimercapto-s-triazine, 2-anilino-4,6-dimercapto-s-triazine, 2,4,6-trimercapto-s-triazine, or other six-member heterocyclic compound which contains nitrogen atoms; may be mentioned.

Among these as well, from the viewpoint that the adhesion of the obtained resin film can be raised more, the number of the acidic groups in the compound which has an acidic group is preferably two or more.

Further, among the compounds which have an acidic group or thermally latent acidic group, as specific examples of the compound which has a thermally latent acidic group, a compound which converts the acidic group of the compound which has an acidic group to a thermally latent acidic group may be mentioned. For example, it is possible to use 1,2,4-benzenetricarboxylic acid tris(1-propoxyethyl) which is obtained by converting the carboxy group of the 1,2,4-benzenetricarboxylic acid to a block carboxylic acid group as a compound which has a thermally latent acidic group. From the viewpoint of further increasing the adhesion of the obtained resin film, the number of the thermally latent acidic groups in the compound which has a thermolatent acidic group is preferably two or more.

Further, in the negative type photosensitive resin composition of the present invention, the content of the compound which has an acidic group or thermally latent acidic group is preferably 0.1 to 50 parts by weight with respect to 100 parts by weight of the resin compound (A), more preferably 1 to 45 parts by weight, furthermore preferably 2 to 40 parts by weight, particularly preferably 3 to 30 parts by weight in range. By making the amount of use of the compound which has an acidic group or thermally latent acidic group in the above range, it is possible to make the resin composition one excellent in liquid stability.

Further, the negative type photosensitive resin composition of the present invention may contain, in a range in which the effects of the present invention are not impaired, as desired a surfactant, acidic compound, coupling agent or their derivatives, sensitizer, latent acid generator, antioxidant, photostabilizer, defoamer, pigment, dye, filler, or other compounding agent etc. Among these, for example, for the surfactants, coupling agents or their derivatives, sensitizers, antioxidants, and photostabilizers, ones which are described in Japanese Patent Publication No. 2011-75609A etc. may be used.

The method of preparation of the negative type photosensitive resin composition of the present invention is not particularly limited. It is sufficient to mix the ingredients which form the negative type photosensitive resin composition by a known method.

The method of mixing is not particularly limited, but mixing a solution or dispersion which is obtained by dissolving or dispersing the ingredients which form the negative type photosensitive resin composition in a solvent is preferable. Due to this, a negative type photosensitive resin composition can be obtained in the form of a solution or dispersion.

The method of dissolving or dispersing the ingredients which form the negative type photosensitive resin composition in a solvent may be based on the ordinary method. Specifically, this may be performed by stirring using a stirring bar and magnetic stirrer, high speed homogenizer, disperser, planetary stirrer, twin-screw stirrer, ball mill, triple roll, etc. Further, the ingredients may also be dissolved or dispersed in a solvent, then for example filtered using a filter with a pore size of 0.5 μm or so etc.

The solid content concentration of the negative type photosensitive resin composition of the present invention is usually 1 to 70 wt %, preferably 5 to 60 wt %, more preferably 10 to 50 wt %. If the solid content concentration is in this range, the solution stability, coatability, and uniformity of thickness and flatness etc. of the resin film which is formed are obtained in a good balance.

(Resin Film)

The resin film of the present invention may be obtained by using the above-mentioned negative type photosensitive resin composition of the present invention. As the resin film of the present invention, one which is obtained by forming the above-mentioned negative type photosensitive resin composition of the present invention on a board is preferable.

As the board, for example, a printed circuit board, silicon wafer board, glass board, plastic board, etc. can be used. Further, a glass board or plastic board etc. on which thin transistor type liquid crystal display devices, color filters, black matrices, etc. are formed, used in the field of displays, may be suitably used.

The method of forming the resin film is not particularly limited. For example, the coating method or film lamination method or other methods may be used.

The coating method is, for example, the method of coating the negative type photosensitive resin composition, then heating it to dry and remove the solvent. As the method of coating the negative type photosensitive resin composition, for example, the spray method, spin coat method, roll coat method, die coat method, doctor blade method, rotary coat method, bar coat method, screen printing method, or other various types of methods may be employed. The heating and drying conditions differ depending on the types and ratios of the ingredients, but usually is 30 to 150° C., preferably 60 to 120° C., usually for 0.5 to 90 minutes, preferably 1 to 60 minutes, more preferably 1 to 30 minutes.

The film laminating method is the method of coating the negative type photosensitive resin composition on a resin film or metal film or other B-stage film-forming base material, then heating and drying it to remove the solvent and obtain the B-stage film, then laminating this B-stage film. The heating and drying conditions can be suitably selected in accordance with the type of the ingredients and the ratio of formulation, but the heating temperature is usually 30 to 150° C. and the heating time is usually 0.5 to 90 minutes. The film lamination can be performed by using a pressure laminator, press, vacuum laminator, vacuum press, roll laminator, or other press bonder.

The thickness of the resin film is not particularly limited and may be suitably set in accordance with the application, but when the resin film is a protective film for active matrix board use or a sealing film for organic EL device board use, the thickness of the resin film is preferably 0.1 to 100 μm, more preferably 0.5 to 50 μm, furthermore preferably 0.5 to 30 μm.

Further, the negative type photosensitive resin composition of the present invention is one which includes the epoxy group-containing cross-linking agent (E), so the resin film which is formed by the above coating method or film lamination method may be cross-linked. Such cross-linking is usually performed by heating. The heating method may, for example, be performed by using a hot plate, oven, etc. The heating temperature is usually 180 to 250° C., while the heating time is suitably selected in accordance with the area or thickness of the resin film, the equipment used, etc. For example, when using a hot plate, the treatment is usually performed for 5 to 60 minutes, while when using an oven, it is usually 30 to 90 minutes in range. The heating may in accordance with need be performed in an inert gas atmosphere. The inert gas may be one which does not contain oxygen and which does not cause the resin film to oxidize. For example, nitrogen, argon, helium, neon, xenon, krypton, etc. may be mentioned. Among these as well, nitrogen and argon are preferable. In particular, nitrogen is preferable. In particular, an inert gas with an oxygen content of 0.1 vol % or less, preferably 0.01 vol % or less, in particular nitrogen, is preferred. These inert gases may be used alone or in combinations of two or more types.

Further, when the resin film comprised of the above-mentioned negative type photosensitive resin composition is a protective film for an active matrix board, a sealing film for organic EL device board use, or other film formed with a predetermined pattern, it may be patterned. As the method of patterning the resin film, for example, the method of forming a resin film before patterning, irradiating the resin film before patterning with active radiation to cause the radical-generating type photopolymerization initiator (D) to act to form a latent image pattern and then bringing the resin film which has the latent image pattern into contact with the development solution so as to actualize the pattern etc. may be mentioned.

The radiation is not particularly limited so long as one which activates the radical-generating type photopolymerization initiator (D) which is contained in the negative type photosensitive resin composition and can change the alkali solubility of the resin composition which contains the radical-generating type photopolymerization initiator (D), but light of a wavelength of 400 nm or less is preferable. Specifically, UV rays, g-rays or i-rays or other single wavelength UV rays, KrF excimer laser light, ArF excimer laser light, or other light beams; particle beams such as electron beams; etc. may be used. The method of irradiating such active radiation selectively in a pattern manner to form a latent image pattern may be based on an ordinary method. For example, a method of using a reduction projection exposure apparatus etc. to irradiate UV rays, g-rays, i-rays, KrF excimer laser light, ArF excimer laser light, or other light beams through a desired mask pattern, the method of using electron beams or other particle beams to draw patterns, etc. may be used. When using light beams as active radiation, single wavelength light or mixed wavelength light may be used. The irradiating conditions may be suitably selected in accordance with the radiation which is used, but for example the amount of irradiation is usually 10 to 1,000 mJ/cm², preferably 50 to 500 mJ/cm² in range and is determined in accordance with the irradiation time and illuminance. After irradiating the active radiation in this way, in accordance with need, the resin film is heat treated at 60 to 130° C. or so in temperature for 1 to 2 minutes or so.

Next, the latent image pattern which was formed on the resin film before patterning is developed to actualize it. As the developing solution, usually an aqueous solution of an alkaline compound is used. As the alkaline compound, for example, an alkali metal salt, amine, or ammonium salt can be used. The alkaline compound may be an inorganic compound or may be an organic compound. As specific examples of these compounds, sodium hydroxide, potassium hydroxide, sodium carbonate, sodium silicate, sodium metasilicate, or other alkali metal salt; ammonia water; ethylamine, n-propylamine, or other primary amine; diethylamine, di-n-propylamine, or other secondary amine; triethylamine, methyldiethylamine, or other tertiary amine; tetramethylarrimonium hydroxide, tetraethylammonium hydroxide, tetrabutylammonium hydroxide, choline, or other quaternary ammonium salt; dimethylethanolamine, triethanolamine, or other alcoholamine; pyrrole, piperidine, 1,8-diazabicyclo[5.4.0]undec-7-ene, 1,5-diazabicyclo[4.3.0]non-5-ene, methylpyrrolidone, or other cyclic amine; etc. may be mentioned. These alkaline compounds may be used alone or in combination of two or more types.

As the aqueous medium of the alkali aqueous solution, water; methanol, ethanol, or other water soluble organic solvent may be used. The alkali aqueous solution may be one in which a suitable quantity of a surfactant etc. is added.

As the method for bringing a developing solution into contact with a resin film which has a latent image pattern, for example, the puddle method, spray method, dipping method, etc. may be used. The development is suitably selected from usually 0 to 100° C., preferably 5 to 55° C., more preferably 10 to 30° C. in range and usually for 30 to 180 seconds in range.

The resin film on which the target pattern is formed in this way can if necessary be rinsed by a rinse solution so as to remove the development residue. After the rinsing, the remaining rinse solution is removed by compressed air or compressed nitrogen.

In the present invention, the resin film can be subjected to a cross-linking reaction after patterning. The cross-linking may be performed in accordance with the above-mentioned method.

(Electronic Device)

The electronic device of the present invention is provided with the above-mentioned resin film of the present invention. The electronic device of the present invention is not particularly limited, but various types of semiconductor devices may be mentioned. Specifically, an active matrix board, organic EL device board, integrated circuit device board, solid state imaging device board, etc. may be mentioned.

The active matrix board constituting one example of the electronic device of the present invention is not particularly limited, but a board on which thin film transistors (TFT) and other switching devices are arranged in a matrix and on which gate signal lines which supply gate signals for driving the switching devices and source signal lines for supplying display signals to the switching devices are provided to intersect each other etc. may be illustrated. Further, as the thin film transistor constituting one example of a switching device, one configured having a gate electrode, gate insulating layer, semiconductor layer, source electrode, drain electrode, etc. on the board may be mentioned.

Furthermore, as an organic EL device board constituted as one example of the electronic device of the present invention, for example, one configured having a board on which light emitting parts each comprised of a cathode, hole injection and transport layer, organic light emitting layer constituted as a semiconductor layer, electron injection layer, anode, etc. and a picture element separating film for separating the light emitting parts may be illustrated.

Further, when the electronic device of present invention is a semiconductor device, the resin film which forms part of the electronic device of present invention is preferably a resin film which is formed in contact with the semiconductor device surface or with a semiconductor layer which is included in the semiconductor device. In particular, when the electronic device of present invention is an active matrix board or organic EL device board, it may be configured as follows. That is, for example, when the electronic device of the present invention is an active matrix board, the above-mentioned resin film of the present invention can be made a protective film which is formed on the surface of the active matrix board or a gate insulating film which is formed in contact with the semiconductor layer of the thin film transistor which forms part of the semiactive matrix board (for example, amorphous silicon layer). Alternatively, when the electronic device of the present invention is an organic EL device board, it may be made a sealing film which is formed on the surface of the organic EL device board or a picture element separating film for separating the light emitting parts which are contained in the organic EL device board (usually, each comprised of a cathode, hole injection and transport layer, organic light emitting layer constituted as a semiconductor layer, electron injection layer, anode, etc.).

The negative type photosensitive resin composition of the present invention contains the resin compound (A), (meth)acryloyl compound (B), silane-modified resin (C), radical-generating type photopolymerization initiator (D), and epoxy group-containing cross-linking agent which does not contain a silicon atom (E), so a resin film which is obtained by using the negative type photosensitive resin composition of the present invention is excellent in pattern-forming ability by development. Further, according to the present invention, by applying such a resin film to various types of electronic devices, for example, an active matrix board or organic EL device board or other semiconductor device board, it is possible to pattern a resin film which is included in the electronic device by a finer definition. Due to this, the performance of the electronic device can be raised. Further, the negative type photosensitive resin composition of the present invention is high in solubility with respect to a diluent solvent, so it can be easily prepared to the desired concentration and viscosity. Due to this, it is possible to obtain a resin film which has various thicknesses relatively easily. Further, the solubility with respect to a diluent solvent is high, so on the production line of the electronic device etc., the cleaning of the piping for transporting the resin composition of the present invention by using solvents can be performed extremely easily.

### EXAMPLES

Below, examples and comparative examples will be given to more specifically explain the present invention. The parts and % in the examples are based on weight unless indicated otherwise.

Note that, the definitions of the properties and the methods of evaluation are as explained below.

<Solubility with Respect to Diluent Solvent>

The negative type photosensitive resin composition was made to dissolve in a diluent solvent to give a weight ratio of “negative type photosensitive resin composition:diluent solvent” of 1:10, the obtained solution was allowed to stand for 6 hours, and the solution after standing was observed. The solubility with respect to the diluent solvent was evaluated based on the following. Note that, in the present examples, as the diluent solvent, four types: a thinner (propyleneglycol monomethyl ether:propyleneglycol monomethyl ether acetate: n-butyl alcohol=24.5:10.5:65 (weight ratio)), EDB-82 (dipropyleneglycol methyl ether:n-butyl alcohol=80:20 (weight ratio), propyleneglycol monomethyl ether acetate, and acetone were used. The solubilities with respect to these four types of diluent solvents were evaluated.

G (good): Solution after standing free of turbidity and precipitation and transparent no matter which of four types of diluent solvent is used.

P (poor): Solution after standing suffering from turbidity or precipitation at least at one of four types of diluent solvent.

<Adhesion after Development>

A board comprised of a glass board (product name “Eagle XG”, made by Corning) on which molybdenum was sputtered to a thickness of 100 nm was treated using an ultraviolet ozone cleaning system (made by Technovision, product name “UV-208”) to an ultraviolet ozone cleaning operation (UV-O₃ treatment) for 2 minutes, then was treated by an ultrasonic cleaning operation using pure water for 5 minutes two times, then was treated for silylation using hexamethyl silazane for 90 seconds to obtain a silylated glass board.

Further, the negative type photosensitive resin composition was spin coated on the above obtained silylated glass board, then was prebaked using a hot plate at 120° C. for 115 seconds to form a 3 μm thickness resin film. Next, in order to pattern the resin film, ultraviolet light with a light intensity at 365 nm of 25 mW/cm² was irradiated in an amount of 50 mJ through a mask which had 10 parallel strip-shaped slits (corresponding to spaces) through which light can pass and distances between mutually adjoining slits (corresponding to lines) the same as the slit widths (that is, a mask able to form line and space patterns of the same widths). Note that, as masks, a total of eight types with slit widths and widths between adjoining slits of 2 μm, 3 μm, 4 μm, 5 μm, 10 μm, 25 μm, and 50 μm were used.

Next, a 2.38 wt % tetramethyl ammonium hydroxide aqueous solution was used as the development solution and development was performed at 23° C. for 60 seconds by the puddle method, then ultrapure water was used for rinsing for 30 seconds. Note that, the puddle method is the method of forming a puddle of the development solution on the resin film. Due to the above, resin films which have patterns (line and space patterns) which are transferred from a mask (that is, eight types of resin film which have line widths and space widths of 2 μm, 3 μm, 4 μm, 5 μm, 10 μm, 25 μm, and 50 μm) were prepared on a glass board. In the present example, a positive type resin composition which has a radiantion-sensitive ability is used to prepare a resin film, so in the resin film, the parts corresponding to the slit parts of the mask correspond to parts from which the resin film is removed. These are called space parts. The parts which correspond to the distances between adjoining slits of the mask correspond to parts where the resin film remains. These are called line parts. Further, the glass boards on which resin films which have such patterns are formed were used as samples for measurement of the adhesion. The adhesion was evaluated by the following method.

That is, each above obtained sample for measurement of the adhesion was evaluated by observation using an optical microscope. Specifically, first, the presence of any peeling of line parts from the board was checked for. If there are no peeled off line parts, the adhesion can be said to be high. If there are peeled off line parts, it is confirmed up to what μm width at a maximum the line parts were peeled off and these are evaluated by the following criteria. The smaller the line parts in width, the easier the peeling from the board. Therefore, the smaller the maximum width of the width of the line parts which are peeled off from the board, the higher the adhesion can be said to be.

G (good): No peeled off line parts present after development.

P (poor): Peeled off line parts present after development or line parts dissolved away.

<Surface Roughness after Development>

The surface roughness after development was checked by an optical microscope and evaluated by the following criteria.

G (good): No roughness at surface after development

F (fair): Slight relief shapes etc. seen at surface after development.

P (poor): Relief shapes etc. seen at entire surface after development.

<State of Holes at Time of Baking>

The negative type photosensitive resin composition was spin coated on a silylated glass board which was obtained in the same way as the above-mentioned evaluation of the adhesion after development, then was prebaked using a hot plate at 120° C. for 115 seconds to form a 3 μm thickness resin film. Next, the obtained resin film was irradiated with 50 mJ of ultraviolet light with a light intensity at 365 nm of 5 mW/cm² through a mask with a 8 μm×8 μm hole pattern. Next, a 2.38 wt % tetramethylammonium hydroxide aqueous solution was used for development at 23° C. for 60 seconds, then ultrapure water was used to rinse the film for 30 seconds to form a pattern of contact holes.

Further, the resin film which has the pattern of contact holes which was obtained in this way was examined using an optical microscope for the size of the contact holes which were formed and was evaluated by the following criteria.

G (good): length of one side of contact holes formed of 6 μm to 8 μm

F (fair): length of one side of contact holes formed of 4 μm to less than 6 μm

P (poor): length of one side of contact holes formed of 0 μm to less than 4 μm

### Synthesis Example 1

### Preparation of Poly(methyltrimethoxysilane)

To a flask equipped with a stirring device, reflux cooling tube, and thermometer, methyltrimethoxysilane 136 parts and methanol 32 parts were charged. Next, while stirring these at normal temperature, an aqueous solution of ion exchanged water 13.5 parts (0.75 molar equivalent with respect to methyl trimethoxysilane) in which concentrated hydrochloric acid 0.1 part was dissolved was added dropwise over 5 minutes and the reaction was continued for 4 hours. Further, after 4 hours of reaction, the reflux cooling tube was replaced with a fractional distillation tube, then the low boiling point components were distilled off under a temperature of 80° C. and normal pressure over 30 minutes, then the solution was distilled under a temperature of 100° C. and pressure of 0.3 KPa to obtain poly(methyltrimethoxysilane). The obtained poly(methyltrimethoxysilane) was analyzed by gel permeation chromatography (GPC), whereupon the obtained poly(methyltrimethoxysilane) was an oligomer which had a weight average molecular weight of 490 (converted to polystyrene) and had a content of unreacted silane compounds and low condensates of 7% or less (GPC area percentage).

### Synthesis Example 2

### Preparation of Silane-Modified Epoxy Resin (C-1) Solution

To a reaction apparatus equipped with a stirrer, cooling tube, and thermometer, a bisphenol A type epoxy resin (epoxy equivalent: 480 g/eq 800.0 parts and diethyleneglycol dimethyl ether 960.0 parts were added and dissolved at 80° C. Further, to this, the poly(methyltrimethoxysilane) which was obtained in Synthesis Example 1, 605.0 parts and a catalyst constituted by dibutyltin laurate 2.3 parts were added and reacted at 80° C. for 5 hours for demethanolization to obtain a silane-modified epoxy resin (C-1) solution. Note that, the obtained silane-modified epoxy resin had an effective ingredient (after curing) of 50% and a “weight converted to silica/weight of bisphenol type epoxy resin” (weight ratio) of 0.51 and an epoxy equivalent of 1400 g/eq. Further, it was confirmed by ¹H-NMR that 87 mol % of the methoxy groups of the partial condensate ingredient of the poly(methyltrimethoxysilane) were held.

### Synthesis Example 3

### Preparation of Silane-Modified Phenol Resin (C-2)

To a reaction apparatus equipped with a stirrer, distributor, thermometer, and nitrogen gas introduction tube, a novolac type phenol resin (made by Arakawa Chemical Industries, product name Tamanol) 800 parts and poly(methyltrimethoxysilane) which was obtained in Synthesis Example 1, 590.3 parts were added and melted and mixed at 100° C. To this, a catalyst constituted by dibutyltin dilaurate 3 parts was added, the mixture was reacted at 110° C. for 7 hours for demethanolization, and, further, methanol 80 parts was distilled off from this to obtain the silane-modified phenol resin (C-2).

### Example 1

To a carboxyl group-containing resin compound (A1) constituted by a carboxylic acid anhydride-modified cresol novolac type epoxy acrylate (product name “NK Oligo EA-7140”, made by Shin-Nakamura Chemical, weight average molecular weight: 1700) 70 parts dissolved in propyleneglycol monomethyl ether acetate 30 parts to obtain a solution 100 parts, a carboxyl group-free resin compound (A2) constituted by a mixture of urethane acrylate and polyoxypropylene monoacrylate (product name “NK Oligo UA-4200”, made by Shin-Nakamura Chemical) 20 parts, a (meth)acryloyl compound (B) constituted by a mixture of dipentaerythritol pentaacrylate and dipentaerythritol hexaacrylate (product name “Aronix M402”, made by Toagosei, weight average molecular weight: 560) 50 parts, a silane-modified resin (C) constituted by the silane-modified epoxy resin (C-1) solution which was obtained in Synthesis Example 2, 10 parts (as silane-modified epoxy resin (C-1): 5 parts), a radical-generating type photopolymerization initiator (D) constituted by [1-(4-phenylsulfanylbenzoyl)heptylidene amino]benzoate 1.5 parts, an epoxy group-containing cross-linking agent (E) constituted by polyethyleneglycol diglycidyl ether (product name “Denacol EX850”, made by Nagase ChemteX, molecular weight: 218) 100 parts, a compound which has an acidic group constituted by diphenolic acid 1 part, and an organic solvent constituted by diethyleneglycol ethylmethyl ether 100 parts, a polyether-modified silicone oil (product name “KP341”, made by Shin-Etsu Silicone) 300 ppm was added and mixed and stirred to dissolve, then the solution was filtered by a pore size 0.45 μm polytetrafluoroethylene filter to prepare a negative type photosensitive resin composition. Note that, the carboxyl group-free resin compound (A2) constituted by a mixture of urethane acrylate and polyoxypropylene monoacrylate also corresponds to the resin compound (A3) which has a urethane structure.

Further, the above obtained resin composition was used to evaluate the solubility in a diluent solvent, the adhesion after development, and the state of holes at the time of baking. The results are shown in Table 1.

### Example 2

Except for changing the amount of the epoxy group-containing cross-linking agent (E) constituted by polyethyleneglycol diglycidyl ether from 100 parts to 50 parts, the same procedure was followed as in Example 1 to obtain a negative type photosensitive resin composition and similarly evaluate it. The results are shown in Table 1.

### Example 3

Except for changing the amount of the (meth)acryloyl compound (B) constituted by a mixture of dipentaerythritol pentaacrylate and dipentaerythritol hexaacrylate from 50 parts to 30 parts, the same procedure was followed as in Example 1 to obtain a negative type photosensitive resin composition and similarly evaluate it. The results are shown in Table 1.

### Example 4

Except for changing the amount of the silane-modified resin (C) constituted by a silane-modified epoxy resin (C-1) solution from 10 parts to 40 parts (as silane-modified epoxy resin (C-1): 20 parts), the same procedure was followed as in Example 1 to obtain a negative type photosensitive resin composition and similarly evaluate it. The results are shown in Table 1.

### Example 5

Except for using as the carboxyl group-containing resin compound (A1), instead of the carboxylic acid anhydride-modified cresol novolac type epoxy acrylate (product name “NK Oligo EA-7140”, made by Shin-Nakamura Chemical, weight average molecular weight: 1700) 70 parts, a carboxylic acid anhydride-modified cresol novolac type epoxy acrylate (product name “NK Oligo EA-6340”, made by Shin-Nakamura Chemical, weight average molecular weight: 1100) 70 parts, the same procedure was followed as in Example 1 to obtain a negative type photosensitive resin composition and similarly evaluate it. The results are shown in Table 1.

### Example 6

Except for using as the carboxyl group-containing resin compound (A1), instead of the carboxylic acid anhydride-modified cresol novolac type epoxy acrylate (product name “NK Oligo EA-7140”, made by Shin-Nakamura Chemical, weight average molecular weight: 1700) 70 parts, a carboxylic acid anhydride-modified cresol novolac type epoxy acrylate (product name “NK Oligo EA-7440”, made by Shin-Nakamura Chemical, weight average molecular weight: 3900) 70 parts, the same procedure was followed as in Example 1 to obtain a negative type photosensitive resin composition and similarly evaluate it. The results are shown in Table 1.

### Example 7

Except for using as the (meth)acryloyl compound (B), instead of the mixture of dipentaerythritol pentaacrylate and dipentaerythritol hexaacrylate 50 parts, a mixture of tris(2-acryloyloxyethyl) isocyanulate and bis(2-acryloyloxyethyl)(2-hydroxyethyl)isocyanulate (product name “Aronix M313”, made by Toagosei, weight average molecular weight: 400) 50 parts, the same procedure was followed as in Example 1 to obtain a negative type photosensitive resin composition and similarly evaluate it. The results are shown in Table 1.

### Example 8

Except for using as the (meth)acryloyl compound (B), instead of the mixture of dipentaerythritol pentaacrylate and dipentaerythritol hexaacrylate 50 parts, a mixture of pentaerythritol triacrylate and pentaerythritol tetraacrylate (product name “Aronix M450”, made by Toagosei, weight average molecular weight: 345) 50 parts, the same procedure was followed as in Example 1 to obtain a negative type photosensitive resin composition and similarly evaluate it. The results are shown in Table 1.

### Example 9

Except for using as the epoxy group-containing cross-linking agent (E), instead of the polyethyleneglycol diglycidyl ether 100 parts, 3,4-epoxycyclohexenylmethyl-3′,4′-epoxycyclohexene carboxylate (product name “Celloxide 2021”, made by Daicel Corporation, molecular weight: 252) 100 parts, the same procedure was followed as in Example 1 to obtain a negative type photosensitive resin composition and similarly evaluate it. The results are shown in Table 1.

### Example 10

Except for using as the epoxy group-containing cross-linking agent (E), instead of the polyethyleneglycol diglycidyl ether 100 parts, a diglycerin polyglycidyl ether (product name “SR-DGE”, made by Sakamoto Yakuhin Kogyo, molecular weight: 390) 100 parts, the same procedure was followed as in Example 1 to obtain a negative type photosensitive resin composition and similarly evaluate it. The results are shown in Table 1.

### Example 11

Except for using as the epoxy group-containing cross-linking agent (E), instead of the polyethyleneglycol diglycidyl ether 100 parts, a sorbitol-based polyglycidylether (product name “SR-SEP”, made by Sakamoto Yakuhin Kogyo, molecular weight: 518) 100 parts, the same procedure was followed as in Example 1 to obtain a negative type photosensitive resin composition and similarly evaluate it. The results are shown in Table 1.

### Example 12

Except for using as the silane-modified resin (C), instead of the silane-modified epoxy resin (C-1) 5 parts, the silane-modified phenol resin (C-2) which was obtained in Synthesis Example 3, 5 parts, the same procedure was followed as in Example 1 to obtain a negative type photosensitive resin composition and similarly evaluate it. The results are shown in Table 1.

### Example 13

Except for changing the amount of the carboxyl group-free resin compound (A2) constituted by a mixture of the urethane acrylate and polyoxypropylene monoacrylate from 20 parts to 10 parts, the same procedure was followed as in Example 1 to obtain a negative type photosensitive resin composition and similarly evaluate it. The results are shown in Table 1.

### Example 14

Except for changing the amount of the carboxyl group-free resin compound (A2) constituted by a mixture of urethane acrylate and polyoxypropylene monoacrylate from 20 parts to 50 parts, the same procedure was followed as in Example 1 to obtain a negative type photosensitive resin composition and similarly evaluate it. The results are shown in Table 1.

### Example 15

Except for not using the carboxyl group-free resin compound (A2) constituted by a mixture of urethane acrylate and polyoxypropylene monoacrylate, the same procedure was followed as in Example 1 to obtain a negative type photosensitive resin composition and similarly evaluate it. The results are shown in Table 1.

### Comparative Example 1

Except for not using the carboxyl group-free resin compound (A2) constituted by a mixture of urethane acrylate and polyoxypropylene monoacrylate and the silane-modified resin (C) constituted by the silane-modified epoxy resin (C-1), the same procedure was followed as in Example 2 to obtain a negative type photosensitive resin composition and similarly evaluate it. The results are shown in Table 1.

### Comparative Example 2

Except for not using the carboxyl group-free resin compound (A2) constituted by a mixture of urethane acrylate and polyoxypropylene monoacrylate and the epoxy group-containing cross-linking agent (E) constituted by the polyethyleneglycol diglycidyl ether, the same procedure was followed as in Example 1 to obtain a negative type photosensitive resin composition and similarly evaluate it. The results are shown in Table 1.

### Comparative Example 3

Except for not using the (meth)acryloyl compound (B) constituted by a mixture of dipentaerythritol pentaacrylate and dipentaerythritol heyaacrylate, the same procedure was followed as in Example 1 to obtain a negative type photosensitive resin composition and similarly evaluate it. The results are shown in Table 1.

TABLE 1

| | | Example | | | | | | | | |
|---|---|---|---|---|---|---|---|---|---|---|
| | | 1 | 2 | 3 | 4 | 5 | 6 | 7 | 8 | 9 |
| Composition of negative type photosensitive resin composition | | | | | | | | | | |
| Carboxylic acid anhydride-modified cresol novolac type | (part) | 70 | 70 | 70 | 70 | | | 70 | 70 | 70 |
| epoxy acrylate (Mw: 1700), NK Oligo EA7140 | | | | | | | | | | |
| Carboxylic acid anhydride-modified cresol novolac type | (part) | | | | | 70 | | | | |
| epoxy acrylate (Mw: 1100), NK Oligo EA6340 | | | | | | | | | | |
| Carboxylic acid anhydride-modified cresol novolac type | (part) | | | | | | 70 | | | |
| epoxy acrylate (Mw: 3900) NK Oligo EA7440 | | | | | | | | | | |
| Urethane acrylate and polyoxypropylene monoacrylate | (part) | 20 | 20 | 20 | 20 | 20 | 20 | 20 | 20 | 20 |
| mixture, NK Oligo UA4200 | | | | | | | | | | |
| Dipentaerythritol pentaacrylate and dipentaerythritol | (part) | 50 | 50 | 30 | 50 | 50 | 50 | | | 50 |
| hexaacrylate mixture (Mw: 560), Aronix M402 | | | | | | | | | | |
| Tris(2-acryloyloxyethyl)isocyanulate and bis(2-acryloyloxyethyl) | (part) | | | | | | | 50 | | |
| (2-hydroxyethyl)isocyanulate mixture (Mw: 400), Aronix M313 | | | | | | | | | | |
| Pentaerythritol triacrylate and pentaerythritol tetraacrylate | (part) | | | | | | | | 50 | |
| mixture (Mw: 345), Aronix M450 | | | | | | | | | | |
| Silane-modified epoxy resin (C-1) | (part) | 5 | 5 | 5 | 20 | 5 | 5 | 5 | 5 | 5 |
| Silane-modified phenol resin (C-2) | (part) | | | | | | | | | |
| [1-(4-phenylsulfanylbenzoyl)heptylidene amino]benzoate | (part) | 1.5 | 1.5 | 1.5 | 1.5 | 1.5 | 1.5 | 1.5 | 1.5 | 1.5 |
| Polyethyleneglycol diglycidyl ether | (part) | 100 | 50 | 100 | 100 | 100 | 100 | 100 | 100 | |
| 3,4-epoxycyclohexenylmethyl-3′,4′-epoxycyclohexene carboxylate | (part) | | | | | | | | | 100 |
| Diglycerin polyglycidyl ether | (part) | | | | | | | | | |
| Sorbitol-based polyglycidyl ether | (part) | | | | | | | | | |
| Diphenolic acid | (part) | 1 | 1 | 1 | 1 | 1 | 1 | 1 | 1 | 1 |
| Evaluation | | | | | | | | | | |
| Solubility in diluent solvent | | G | G | G | G | G | G | G | G | G |
| Adhesion after development | | G | G | G | G | G | G | G | G | G |
| Surface roughness after development | | G | G | F | F | G | G | F | F | F |
| State of holes at baking | | G | G | G | G | G | F | G | G | G |
| | | Example | | | | | | Comp. ex. | | |
| | | 10 | 11 | 12 | 13 | 14 | 15 | 1 | 2 | 3 |
| Composition of negative type photosensitive resin composition | | | | | | | | | | |
| Carboxylic acid anhydride-modified cresol novolac type | (part) | 70 | 70 | 70 | 70 | 70 | 70 | 70 | 70 | 70 |
| epoxy acrylate (Mw: 1700), NK Oligo EA7140 | | | | | | | | | | |
| Carboxylic acid anhydride-modified cresol novolac type | (part) | | | | | | | | | |
| epoxy acrylate (Mw: 1100), NK Oligo EA6340 | | | | | | | | | | |
| Carboxylic acid anhydride-modified cresol novolac type | (part) | | | | | | | | | |
| epoxy acrylate (Mw: 3900) NK Oligo EA7440 | | | | | | | | | | |
| Urethane acrylate and polyoxypropylene monoacrylate | (part) | 20 | 20 | 20 | 10 | 50 | | | | 20 |
| mixture, NK Oligo UA4200 | | | | | | | | | | |
| Dipentaerythritol pentaacrylate and dipentaerythritol | (part) | 50 | 50 | 50 | 50 | 50 | 50 | 50 | 50 | |
| hexaacrylate mixture (Mw: 560), Aronix M402 | | | | | | | | | | |
| Tris(2-acryloyloxyethyl)isocyanulate and bis(2-acryloyloxyethyl) | (part) | | | | | | | | | |
| (2-hydroxyethyl)isocyanulate mixture (Mw: 400), Aronix M313 | | | | | | | | | | |
| Pentaerythritol triacrylate and pentaerythritol tetraacrylate | (part) | | | | | | | | | |
| mixture (Mw: 345), Aronix M450 | | | | | | | | | | |
| Silane-modified epoxy resin (C-1) | (part) | 5 | 5 | | 5 | 5 | 5 | | 5 | |
| Silane-modified phenol resin (C-2) | (part) | | | 5 | | | | | | 5 |
| [1-(4-phenylsulfanylbenzoyl)heptylidene amino]benzoate | (part) | 1.5 | 1.5 | 1.5 | 1.5 | 1.5 | 1.5 | 1.5 | 1.5 | 1.5 |
| Polyethyleneglycol diglycidyl ether | (part) | | | 100 | 100 | 100 | 100 | | | 100 |
| 3,4-epoxycyclohexenylmethyl-3′,4′-epoxycyclohexene carboxylate | (part) | | | | | | | 100 | | |
| Diglycerin polyglycidyl ether | (part) | 100 | | | | | | | | |
| Sorbitol-based polyglycidyl ether | (part) | | 100 | | | | | | | |
| Diphenolic acid | (part) | 1 | 1 | 1 | 1 | 1 | 1 | 1 | 1 | 1 |
| Evaluation | | | | | | | | | | |
| Solubility in diluent solvent | | G | G | G | G | G | G | G | G | G |
| Adhesion after development | | G | G | G | F | G | F | P | P | P |
| Surface roughness after development | | F | F | G | G | F | G | F | F | F |
| State of holes at baking | | G | G | G | G | G | F | G | P | P |

As shown in Table 1, the negative type photosensitive resin compositions of Examples 1 to 14 which contain the carboxyl group-containing resin compound (A1), carboxyl group-free resin compound (A2), (meth)acryloyl compound (B), silane-modified resin (C), radical-generating type photopolymerization initiator (D), and epoxy group-containing cross-linking agent (E) are high in solubility with respect to a diluent solvent and, further, are excellent in both adhesion after development when made into a resin film and state of holes at the time of baking and are excellent in pattern-forming ability by development.

On the other hand, in Comparative Example 1 which did not use the silane-modified resin (C), the adhesion after development was inferior.

Further, in Comparative Example 2 which did not use the carboxyl group-free resin compound (A2) and Comparative Example 3 which did not use the (meth)acryloyl compound (B), both the adhesion after development and state of holes at the time of baking were inferior.

1. A negative type photosensitive resin composition containing a resin compound (A) which has a weight average molecular weight of 1000 or more, a (meth)acryloyl compound (B), a silane-modified resin (C), a radical-generating type photopolymerization initiator (D), and a silicon atom-free epoxy group-containing cross-linking agent (E), wherein
said resin compound (A) contains a resin compound (A1) which has two or more (meth)acryloyl groups in a molecule and which has a carboxyl group which reacts with said epoxy group and
said (meth)acryloyl compound (B) has a weight average molecular weight of less than 1000 and has two or more (meth)acryloyl groups in a molecule.

2. The negative type photosensitive resin composition as set forth in claim 1, wherein said resin compound (A) further contains a resin compound (A2) which has two or more (meth)acryloyl groups in a molecule and does not have a carboxyl group.

3. The negative type photosensitive resin composition as set forth in claim 1, wherein said resin compound (A) further contains a resin compound (A3) which has two or more (meth)acryloyl groups in a molecule and has a urethane structure.

4. The negative type photosensitive resin composition as set forth in claim 1, wherein said epoxy group-containing cross-linking agent (E) has a molecular weight of 200 to 550, and a content of said epoxy group-containing cross-linking agent (E) is 30 to 150 parts by weight with respect to 100 parts by weight of said resin compound (A).

5. The negative type photosensitive resin composition as set forth in claim 1, wherein said epoxy group-containing cross-linking agent (E) is a glycidyl ether compound.

6. A resin film which is obtained by using the negative type photosensitive resin composition of claim 1.

7. An electronic device which is provided with a resin film as set forth in claim 6.
